(19) United States
(12) Patent Application Publication
(10) Pub. No.: US 2025/0105809 A1
(43) Pub. Date: Mar. 27, 2025

(54) AMPLIFIER WITH PRE-DRIVER HAVING CROSS-COUPLED TRANSISTORS

(71) Applicant: TEXAS INSTRUMENTS INCORPORATED, Dallas, TX (US)

(72) Inventors: Hua Shao, Tucson, AZ (US); Paul Damitio, Tucson, AZ (US); Bharath Karthik Vasan, Tucson, AZ (US); Joel Martin Halbert, Tucson, AZ (US)

(21) Appl. No.: 18/428,170

(22) Filed: Jan. 31, 2024

Related U.S. Application Data
(60) Provisional application No. 63/540,882, filed on Sep. 27, 2023.

(51) Int. Cl. H03F 3/45; H03F 1/30; H03K 17/30

(52) U.S. Cl. CPC H03F 3/45165; H03F 1/302; H03F 3/45174; H03K 17/30; H03F 2200/372

(57) ABSTRACT

An amplifier includes first through sixth transistors. The first transistor is of a first polarity type and has a control terminal and first and second terminals. The second transistor is of a second polarity type and has a control terminal and first and second terminals. The third transistor is of the first polarity type and has a control terminal and first and second terminals. The second terminal of the third transistor is coupled to the first terminal of the second transistor. The fourth transistor is of the second polarity type and has a control terminal and first and second terminals. The first terminal of the fourth transistor is coupled to the second terminal of the second transistor. The fifth transistor has a control terminal coupled to the control terminal of the third transistor. A sixth transistor has a control terminal coupled to the control terminal of the fourth transistor.

### CROSS-REFERENCE TO RELATED APPLICATIONS

This application claims priority to U.S. Provisional Application No. 63/540,882 filed Sep. 27, 2023 and entitled “High Output Drive Output Stage and Method with Low Quiescent Current,” which is hereby incorporated by reference.

### BACKGROUND

Amplifiers, such as power amplifiers, may have output transistors that are sized appropriately to provide relatively high output current. Consequently, the size of transistors in the amplifier's pre-driver also may be relatively large. As a result, the quiescent current in the output transistors (the current through the output transistors with no signal applied to the input of the amplifier) unfortunately may be relatively large thereby generating heat loads that require a suitable thermal packaging design. Further, larger pre-driver transistors may detrimentally impact high speed operation of the amplifier.

### SUMMARY

In one example, an amplifier includes first through sixth transistors. The first transistor is of a first polarity type and has a control terminal and first and second terminals. The second transistor is of a second polarity type and has a control terminal and first and second terminals. The third transistor is of the first polarity type and has a control terminal and first and second terminals. The second terminal of the third transistor is coupled to the first terminal of the second transistor. The fourth transistor is of the second polarity type and has a control terminal and first and second terminals. The first terminal of the fourth transistor is coupled to the second terminal of the second transistor. The fifth transistor has a control terminal coupled to the control terminal of the third transistor. A sixth transistor has a control terminal coupled to the control terminal of the fourth transistor.

In another example, an amplifier includes an input stage circuit having first and second terminals. A voltage gain circuit has a first terminal coupled to the first terminal of the input stage circuit and has a second terminal coupled to the second terminal of the input stage circuit. The voltage gain circuit has a third terminal. The amplifier also has first through sixth transistors. The first transistor is of a first polarity type and has a control terminal coupled to the third terminal and has first and second terminals. The second transistor is of a second polarity type and has a control terminal coupled to the third terminal and has a control terminal and first and second terminals. The third transistor is of the first polarity type and has a control terminal and first and second terminals. The second terminal of the third transistor is coupled to the first terminal of the second transistor. The fourth transistor is of the second polarity type and has a control terminal and first and second terminals. The first terminal of the fourth transistor is coupled to the second terminal of the second transistor. The fifth transistor has a control terminal coupled to the control terminal of the third transistor, and the sixth transistor has a control terminal coupled to the control terminal of the fourth transistor.

In yet another example, an amplifier includes base-connected bipolar junction transistors (BJTs) of different polarity types. The base-connected BJTs have a first terminal and a second terminal. The amplifier has first through sixth transistors. The first transistor is of a first polarity type, has a control terminal coupled to the first terminal of the base-connected BJTs, and has first and second terminals. The second transistor is of a second polarity type, has a control terminal coupled to the second terminal of the base-connected BJTs, and has a control terminal and first and second terminal. The third transistor is of the first polarity type and has a control terminal and first and second terminals. The second terminal of the third transistor is coupled to the first terminal of the second transistor. The fourth transistor is of the second polarity type and has a control terminal and first and second terminals. The first terminal of the fourth transistor is coupled to the second terminal of the second transistor. The fifth transistor has a control terminal coupled to the control terminal of the third transistor. The sixth transistor has a control terminal coupled to the control terminal of the fourth transistor.

### BRIEF DESCRIPTION OF THE DRAWINGS

FIG. 1 is a block diagram of an amplifier including a pre-driver circuit with cross-coupled transistors, in an example.

FIG. 2 is a circuit schematic of an output circuit for the amplifier of FIG. 1 which includes a pre-driver with cross-coupled transistors, in an example.

FIG. 3 is a circuit schematic of an output circuit for the amplifier of FIG. 1 in which the output circuit includes a pre-driver with cross-coupled transistors, in another example.

FIG. 4 is a circuit schematic of an output circuit for the amplifier of FIG. 1 in which the output circuit includes a pre-driver with cross-coupled transistors, in yet another example.

FIG. 5 is a circuit schematic of an output circuit for the amplifier of FIG. 1 in which the output circuit includes a pre-driver with cross-coupled transistors, in another example.

### DETAILED DESCRIPTION

The same reference numbers or other reference designators are used in the drawings to designate the same or similar (either by function and/or structure) features.

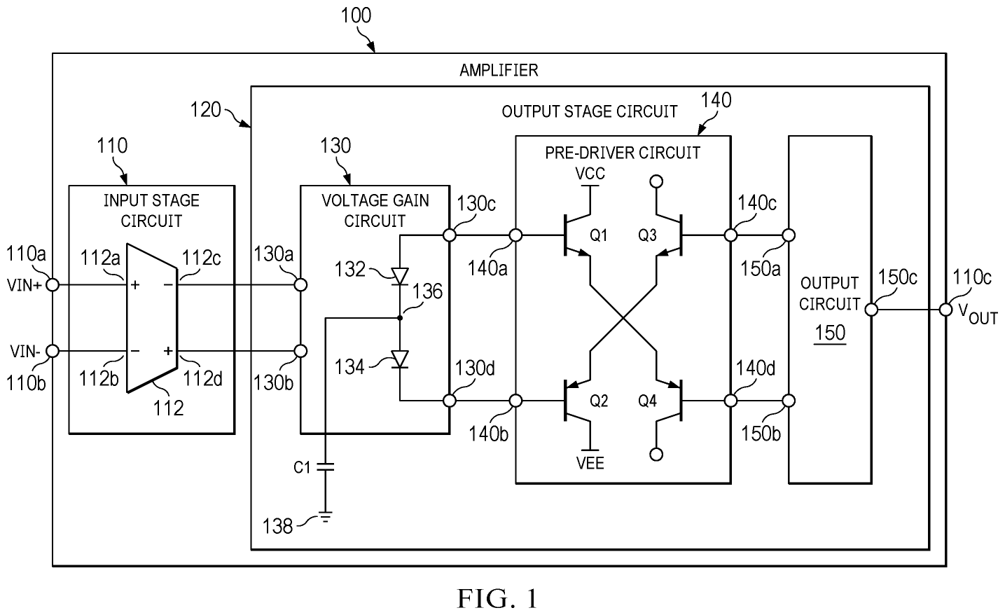

FIG. 1 is a block diagram of an amplifier 100, in an example. Amplifier 100 has input terminals 100a and 100b and output terminal 110c. Amplifier 100 includes an input stage circuit 110 coupled to an output stage circuit 120. In one example, both the input stage circuit 110 and the output stage circuit 120 are provided on the same integrated circuit (IC). In this example, input stage circuit 110 includes a transconductance circuit 112 having input terminals 112a and 112b, coupled to respective amplifier terminals 110a and 110b, and output terminals 112c and 112d.

Output stage circuit 120 includes a voltage gain circuit 130, a pre-driver circuit 140, and an output circuit 150. Voltage gain circuit 130 has input terminals 130a and 130b coupled to output terminals 112c and 112d, respectively, of the transconductance circuit 110. Voltage gain circuit 130 includes output terminals 130c and 130d. Pre-driver circuit 140 has input terminals 140a and 140b and output terminals 140c and 140d. Input terminals 140a and 140b are coupled to respective output terminals 130c and 130d of voltage gain circuit 130. Output circuit 150 includes input terminals 150a and 150b and an output terminal 150c. Input terminals 150a and 150b are coupled to respective output terminals 140c and 140d of pre-driver circuit 140. Output terminal 150c of output circuit 150 is coupled to the amplifier's output terminal 110c.

Voltage gain circuit 130 includes, among other components, diodes 132 and 134 coupled in series between output terminals 130c and 130d. The cathode of diode 132 is coupled to the anode of diode 134 at terminal 136, which may be referred to as the “high impedance” terminal. A compensation capacitor C1 is coupled between high impedance terminal 136 and a ground terminal 138. Compensation capacitor C1 helps to prevent amplifier 100 from oscillating at the frequencies at which the amplifier is intended to operate. Voltage gain circuit 130 provides a voltage gain between the differential voltage input to the amplifier, VIN+−VIN−, and the voltage on high impedance terminal 136.

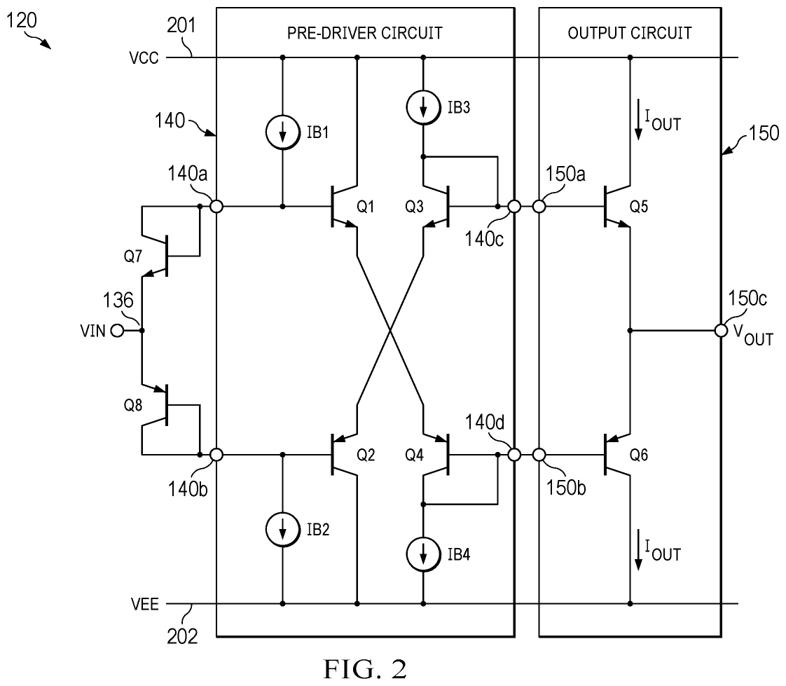

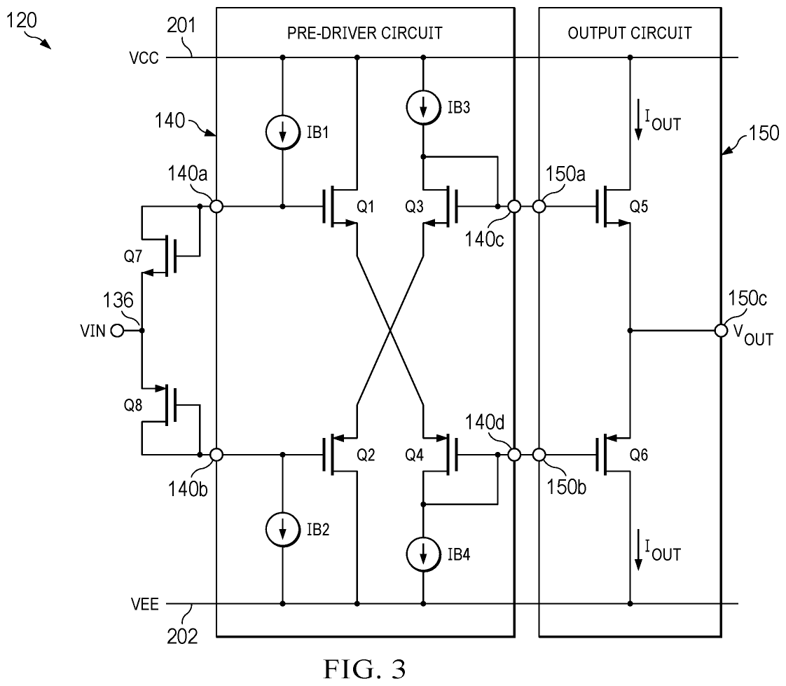

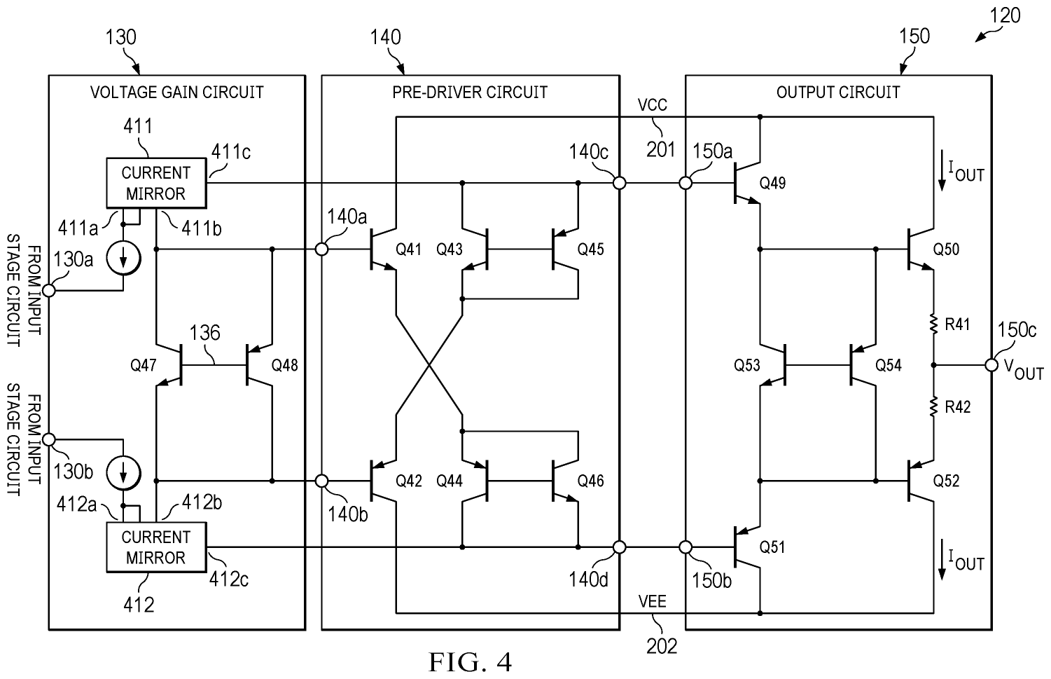

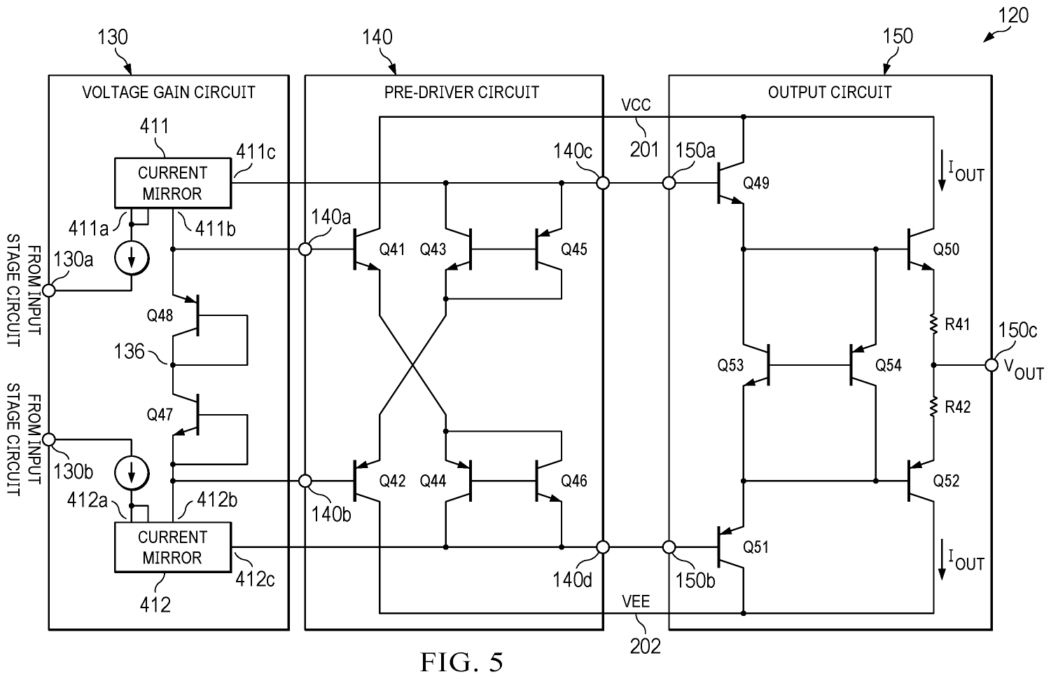

Pre-driver circuit 140 includes transistors Q1, Q2, Q3, and Q4. In this example, transistors Q1-Q4 are bipolar junction transistors (BJTs). Transistors Q1 and Q3 are of a first polarity type, and transistors Q2 and Q4 are of a second polarity type. In the example of FIG. 1, transistors Q1 and Q3 are NPN transistors (the first polarity type is NPN), and transistors Q2 and Q4 are PNP transistors (the second polarity type is PNP). Transistors Q1-Q4 are cross-coupled in which the emitters of transistors Q1 and Q4 are coupled together, and the emitters of transistors Q2 and Q3 are coupled together. The bases of transistors Q1 and Q2 are coupled to pre-driver circuit input terminals 140a and 140b, respectively. The collector of transistor Q1 is coupled to a first supply voltage terminal (VCC), and the collector of transistor Q2 is coupled to a second supply voltage terminal (VEE). In one example, the supply voltage to amplifier 100 is a dual-supply voltage, e.g., VCC and VEE are +5V and −5V, respectively. In another example, the supply voltage is a single-supply voltage, e.g., VCC is +5V and VEE is ground. The bases of transistors Q3 and Q4 are coupled to pre-driver circuit output terminals 140c and 140d, respectively. In some examples (e.g., in FIGS. 2 and 3, described below), the collector of transistor Q3 is coupled to the first supply voltage terminal VCC, and the collector of transistor Q4 is coupled to the second supply voltage terminal VEE. In other examples (e.g., in FIGS. 4 and 5, described below), the collectors of transistor Q3 and Q4 (transistors Q43 and Q44 in FIGS. 4 and 5) are coupled to the voltage gain circuit 130.

Output circuit 150 includes output transistors (shown in the examples of FIGS. 2-5). As described below, the cross-coupling of transistors Q1-Q4 within pre-driver circuit 140 causes the quiescent current through the output transistors advantageously to be smaller than otherwise would be the case absent the cross-coupled transistors Q1-Q4.

Further, because the quiescent current is relatively small due to the cross-coupled transistors Q1-Q4, transistors Q1-Q4 also can be relatively small. The size of a BJT refers to the cross-sectional area of its emitter-product of the emitter's width and length). In some semiconductor manufacturing processes, the widths of the emitters of the BJTs on a die are the same, and the transistor size is thus a function of the emitter's lengths. Smaller transistors have smaller parasitic capacitance, e.g., base-to-emitter capacitance, than larger transistors. The parasitic capacitance of transistors on a die may vary substantially from transistor to transistor and from die to die for the same processing steps. Transistors Q1-Q4 are directly or indirectly coupled to high impedance terminal 136 to which compensation capacitor C1 is coupled. Because transistors Q1-Q4 are relatively small, transistors Q1-Q4 contribute relatively little parasitic capacitance to high impedance terminal 136. Accordingly, the capacitance selected for capacitor C1 to compensate amplifier 100 can be more accurately determined than would otherwise be the case if a large amount of process-dependent parasitic capacitance was also coupled to high impedance terminal 136. Further, amplifier 100 advantageously also can be used with a slew-boosted input stage, which may be used in high-speed voltage feedback and current feedback amplifiers.

FIG. 2 is a circuit schematic of pre-driver circuit 140 and output circuit 150, in an example. Diodes 132 and 134 are also included in FIG. 2 as diode-connected transistors Q7 and Q8. Output circuit 150 includes transistors, e.g., output transistors, Q5 and Q6. The base of transistor Q5 is coupled to the base of transistor Q3, and the base of transistor Q6 is coupled to the base of transistor Q4. The emitters of transistors Q5 and Q6 are coupled together and to the output terminal 150c. The collector of transistors is coupled to a first supply voltage terminal 201 (VCC), and the collector of transistor Q6 is coupled to a second supply voltage terminal 202 (VEE).

The voltage on high impedance terminal 136 is labeled as voltage VIN in FIG. 2. Voltage VIN is the output voltage from the voltage gain circuit 130. The output voltage VOUT at the amplifier's output terminal 110c is approximately equal to voltage VIN. In this example, transistor Q7 is an NPN transistor, and transistor Q8 is a PNP transistor. Transistors Q3 and Q4 are diode-connected transistors in this example.

Pre-driver circuit 140 includes current source circuits IB1, IB2, IB3, and IB4. Current source circuit IB1 has a terminal coupled to a first supply voltage terminal 201 (VCC) and another terminal coupled to the base of transistor Q1 and base and collector of transistor Q7. Current source circuit IB2 has a terminal coupled to a second supply voltage germinal 202 (VEE) and has a second terminal coupled to the base of transistor Q2 and base and collector of transistor Q8. Current source circuit IB3 has a terminal coupled to the first supply voltage terminal 201 and has another terminal coupled to the collector and base of transistor Q3 and base of transistor Q5. Current source circuit IB4 has a terminal coupled to the second supply voltage terminal 202 and has another terminal coupled to the collector and base of transistor Q4 and base of transistor Q6. In one example, the current produced by current source circuits IB1 and IB2 is approximately the same and is referred to in the equations below as current IB1. Similarly, the current produced by current source circuits IB3 and IB4 is approximately the same and is referred to in the equations below as current IB3.

As mentioned above, output voltage VOUT changes in response to changes in VIN and approximately matches VIN. For example, if voltage VIN increases (e.g., becomes a larger positive voltage), the collector current of transistor Q7 decreases. Because current source circuit IB1 produces a constant level current, the base current of Q1 increases, which in turn causes the collector current through transistor Q4 to increase. Because current source circuit IB4 also produces a constant current, the increase in the collector current of transistor Q4 necessitates a decrease in the base current of transistor Q6. Turning on Q6 weaker causes the output voltage VOUT to be increased relative the voltage VEE of the supply terminal 202 and remain in synch with voltage VIN. A similar response occurs (VOUT decreases relative VCC) responsive to voltage VIN decreasing.

Current Iout represents the current through transistors Q5 and Q6. The equation for the output current Iout as a function of the currents from the current source circuits IB1-IB4 and the size of transistors Q1-Q8 can be derived as follows. The output voltage VOUT from amplifier 100 is approximately the same as voltage VIN. Accordingly, equation (1) reflects the base-to-emitter voltage (VBE) increments starting at high impedance terminal 136 and tracing through transistor Q7 (the addition of the VBE of transistor Q7, through transistor Q1 (a subtraction of the VBE of transistor Q1, through transistor Q4 (another subtraction of the VBE of transistor Q4), and through transistor Q6 (the addition of the VBE of transistor Q6) to output voltage VOUT.

$${VBE}_{Q 7} - {VBE}_{Q 1} - {VBE}_{Q 4} + {VBE}_{Q 6} = 0 \qquad ( Eq . 1 )$$

where VBE_{Q7}, VBE_{Q1}, VBE_{Q4}, and VBE_{Q6}, are the VBE of transistors Q7, Q1, Q4, and Q6, respectively. Substituting the formula for a BJT's VBE as a function of its thermal voltage VT, base current, and saturation current IS into Eq. (1) results in Eq. (2).

$$( {V}_{T} ) ln ( \frac{IB 1}{{IS}_{Q 7}} ) - {V}_{T} ln ( \frac{IB 3}{{IS}_{Q 1}} ) - {V}_{T} ln ( \frac{IB 3}{{IS}_{Q 4}} ) + {V}_{T} * ln ( \frac{IOUT}{{IS}_{Q 6}} ) = 0 \qquad ( Eq . 2 )$$

where “In” is the natural logarithm operator. Solving Eq. (2) for IOUT substituting in the formula for saturation current IS as a function of emitter area results in Eq. (3). Emitter area is the product of its width and its length (L), but the transistors in FIG. 2 all have approximately the same emitter width. Accordingly, Eq. (3) shows emitter area in terms of emitter length, L.

$$IOUT = ( \frac{IB {3}^{2}}{IB 1} ) ( \frac{{L}_{Q 7} * {L}_{Q 6}}{{L}_{Q 1} * {L}_{Q 4}} ) \qquad ( Eq . 3 )$$

where L_{Q7}, L_{Q1}, L_{Q6}, L_{Q4} are the emitter lengths of transistors Q7, Q1, Q6, and Q4, respectively. Performing a similar circuit analysis using transistors Q8, Q2, Q3, and Q5 results in Eq. (4).

$$IOUT = ( \frac{IB {3}^{2}}{IB 1} ) ( \frac{{L}_{Q 8} * {L}_{Q 5}}{{L}_{Q 2} * {L}_{Q 3}} ) \qquad ( Eq . 3 )$$

Equations (3) and (4) show that the quiescent output current (output current with zero differential input voltage to amplifier 100) can be controlled through the selection of current source circuits IB1-IB4, and the relative sizes of transistors Q1-Q8. Quiescent output current IOUT can be reduced through the selection of a smaller emitter lengths of transistors Q7 and Q8. Advantageously, by forming transistors Q7 and Q8 to have smaller emitter lengths, transistors Q7 and Q8 have smaller parasitic capacitance on high impedance terminal 136. Less parasitic capacitance on high impedance terminal 136 enables a more accurate determination of an appropriately-sized compensation capacitor C1 for amplifier 100.

Table I provides two examples of currents IB1 and IB3 and emitter lengths for transistors Q1-Q8 (emitter length of Q1 is L_Q1, emitter length of Q2 is Q_L2, and so on), Both examples result in the same output current IOUT of 8 mA.

TABLE I

| | |
|---|---|
| Example 1 | Example 2 |

| | | | | |
|---|---|---|---|---|
| IOUT | 8 | mA | 8 | mA |
| IB1 | 1 | mA | 1 | mA |
| IB3 | 0.5 | mA | 1 | mA |
| L_Q7 | 80 | μm | 80 | μm |
| L_Q8 | 96 | μm | 96 | μm |
| L_Q1 | 40 | μm | 160 | μm |
| L_Q2 | 48 | μm | 192 | μm |
| L_Q3 | 384 | μm | 384 | μm |
| L_Q4 | 640 | μm | 640 | μm |
| L_Q5 | 6144 | μm | 6144 | μm |
| L_Q6 | 10,240 | μm | 10,240 | μm |

With emitter lengths of 6144 μm and 10,240 μm, respectively, for transistors Q5 and Q6, transistors Q5 and Q6 are fairly large to provide a fairly large output current when needed by amplifier 100. In Examples 1 and 2, transistors Q7 and Q8 have emitter lengths of 80 μm and 94 μm, respectively. In Example 1, the emitter lengths of transistors Q1 and Q2 are 40 μm and 48 μm, respectively, and in Example 2, the emitter lengths of transistors Q1 and Q2 are 160 μm and 192 μm, respectively, which are larger than in Example 1 but are still relatively small. Because current IB3 is squared in Eqs. (3) and (4), the emitter lengths of transistors Q1 and Q2 in Example 2 are four-times their length in Example 1 as a result of current IB3 in Example 2 being twice that of current IB3 in Example 1.

FIG. 3 is substantially the same circuit as in FIG. 2 but the transistors in FIG. 3 are field effect transistors (FETs). For example, transistors Q1, Q3, Q5, and Q7 are n-channel field effect transistors (NFETs), and transistors Q2, Q4, Q6, and Q8 are p-channel field effect transistors (PFETs). NFET transistors are of a first polarity type, and PFET transistors are of a second polarity type. Performing a similar gate-to-source voltage (VGS) analysis from high impedance terminal 136 to output terminal 150c, as the VBE analysis described above, results in Eq. (5).

$${VGS}_{Q 7} - {VGS}_{Q 1} - {VSG}_{Q 4} + {VSG}_{Q 6} = 0 \qquad ( Eq . 5 )$$

where VGS_{Q7}, VGS_{Q1}, VGS_{Q4}, and VGS_{Q6} are VGS voltages of transistors Q7, Q1, Q4, and Q6, respectively. Substituting the formula for a FET's VGS as a function of drain current, transistor size (ratio of channel width (W) to channel length (L)), and a constant Kₙ for an NFET or Kₚ for a PFET (where Kₙ and Kₚ are a function of the corresponding transistor's electron or hole mobility (un, Up) and oxide capacitance per unit area (COX)) for each of the four transistor terms in Eq. 5) results in Eq. (6). The constant Kₙ for an NET is equal to ½*μₙ*Cox and Kₚ for a PFET is equal to ½*μₚ*Cox.

$$\sqrt{\frac{2 * IB 1}{{{K}_{n} ( W / L )}_{Q 7}}} - \sqrt{\frac{2 * IB 3}{{{K}_{n} ( W / L )}_{Q 1}}} - \sqrt{\frac{2 * IB 3}{{{K}_{p} ( W / L )}_{Q 4}}} + \sqrt{\frac{2 * IOUT}{{{K}_{p} ( W / L )}_{Q 6}}} = 0 \qquad ( Eq . 6 )$$

Table II below provides an example, based on Eq. 6) for the sizes of transistors Q1, Q4, Q6, and Q7 for currents IB1 and IB3 equal 1 mA and an output current IOUT of 8 mA. The transistor sizes are specified in Table II as a function of channel widths (W_Q7 for transistor Q7, W_Q1 for transistor Q1, and so on. The values of “x” are relative to the channel width size of transistor Q7 (all of the FETS are assumed to have the same channel length L). In this example, it was assumed that Kₙ=2*Kₚ.

TABLE II

| | Example |
|---|---|
| IOUT | 8 mA |
| IB1 | 1 mA |
| IB3 | 1 mA |
| W_Q7 | x |
| W_Q1 | 2x |
| W_Q4 | 2x |
| W_Q6 | 32x |

FIG. 4 is a circuit schematic of voltage gain circuit 130, pre-driver circuit 140, and output circuit 150, in another example. In this example, voltage gain circuit 130 includes current mirrors 411 and 412 and transistors Q47 and Q48. Pre-driver circuit 140 includes transistors Q41, Q42, Q43, Q44, Q45, and Q46. Transistors Q41-Q44 represent the cross-coupled transistors Q1-Q4, described above. Output circuit 150 includes transistors Q49, Q50, Q51, Q52, Q53, and Q54 and resistors R41 and R42. Transistors Q41, Q43, Q46, Q47, Q49, Q50, and Q53 are NPN BJTs. Transistors Q42, Q44, Q45, Q48, Q51, Q52, and Q54 are PNP BJTs.

Current mirror 411 has an input terminal 411a and output terminals 411b and 411c. Similarly, current mirror 412 has an input terminal 412a and output terminals 412b and 412c. Input terminals 411a and 412a are coupled to respective voltage gain circuit input terminals 130a and 130b. Diodes 132 and 134 in FIG. 1 are transistors Q47 and Q48 in FIG. 4. Transistors Q47 and Q48 are base-connected. The collector of transistor Q47 and the emitter of transistor Q48 are coupled together and to the base of transistor Q41 and output 411b of current mirror 411. The collector of transistor Q48 and the emitter of transistor Q47 are coupled together and to the base of transistor Q42 and output 412b of current mirror 412. Base-connected transistors Q47 and Q48 provide a two VBE voltage drop at DC (direct current) between the bases of transistors Q41 and Q42. High impedance terminal 136 is the bases of transistors Q47 and Q48. Further, the bases of transistors Q41 and Q42 may also be considered as high impedance terminals to which compensation capacitors can be coupled.

The collectors of transistors Q41 and Q42 are coupled to respective voltage supply terminals 201 (VCC) and 202 (VEE), as described above. The emitter of transistor Q41 is coupled to the emitter of transistor Q44 and to the collector of transistor Q46. The emitter of transistor Q42 is coupled to the emitter of transistor Q43 and to the collector of transistor Q45. The collector of transistor Q43 is coupled to the emitter of transistor Q45, the base of transistor Q49, and the output 411c of current mirror 411. Similarly, the collector of transistor Q44 is coupled to the emitter of transistor Q46, the base of transistor Q51, and the output 412c of current mirror 412.

Transistors Q49 and Q50 form a first Darlington transistor pair, and transistors Q51 and Q52 form a second Darlington transistor pair. Base current into transistor Q49 is amplified based on the beta of transistor Q49 to produce its collector current. At least some of the collector current through transistor Q49 is provided to the base of transistor Q50 and amplified based on the beta of transistor Q50 as output current IOUT. Similarly, base current into transistor Q51 is amplified based on the beta of transistor Q51 to produce its collector current. At least some of the collector current through transistor Q51 is provided to the base of transistor Q50 and amplified based on the beta of transistor Q52 as output current IOUT. Transistors Q43 and Q54 are base-connected between the bases of transistors Q50 and Q52. Resistors R41 and R42 are coupled in series between the emitters of transistors Q50 and Q52. The connection between resistors R41 and R42 is output terminal 150c.

In operation, a larger positive differential input voltage to amplifier 100 results in the current at current mirror input terminal 412a being larger than the current at current mirror input terminal 411a. Current at current mirror input terminal 412a being larger than current at current mirror input 411a results in current mirror 412 producing more current through its output terminal 412b to the base of transistor Q42 than current mirror 411 produces through its output terminal 411b to the base of transistor Q41. As a result of the base current of transistor Q42 being larger than the base current of transistor Q41, the current through base-connected transistors Q43 and Q45 is larger, which in turn causes the base current of transistor Q49 to be larger than the base current of transistor Q51. Accordingly, the output current IOUT through transistor Q50 increases as the differential input voltage to amplifier 100 becomes a larger positive value. Similarly, a larger negative differential input voltage to amplifier 100 results in the current at current mirror input terminal 411a being larger than the current at current mirror input terminal 412a, which in turn causes output current IOUT through transistor Q52 to increase.

Similar to the examples of FIGS. 2 and 3, transistors Q47, Q48 and Q41 and Q42 can be sized relatively small to impose relatively little parasitic capacitance on the high impedance terminal 136. Despite transistors Q47, Q48 and Q41 and Q42 being relatively small, output current IOUT can be substantially larger as a result of the cross-coupling of Q41, Q42, Q43 and Q44 and relatively larger transistors Q50 and Q52.

FIG. 5 is a circuit schematic of voltage gain circuit 130, pre-driver circuit 140, and output circuit 150 substantially similar to that of FIG. 4. A difference between FIGS. 4 and 5 is that in FIG. 4, transistors Q47 and Q48 are base-connected between the bases of transistors Q41 and Q42, but in FIG. 5, transistors Q47 and Q48 are diode-connected transistors coupled in series between the bases of transistors Q41 and Q42. All else being equal, all of the current through transistors Q47 and Q48 in FIG. 5 flows through each of transistors Q47 and Q48. However, in FIG. 4, transistors Q47 and Q48 can be smaller than in FIG. 5 because each transistor Q47 and Q48 in FIG. 4 only takes half of the current.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An amplifier, comprising:
a first transistor of a first polarity type and having a control terminal and first and second terminals;
a second transistor of a second polarity type and having a control terminal and first and second terminals;
a third transistor of the first polarity type and having a control terminal and first and second terminals, the second terminal of the third transistor coupled to the first terminal of the second transistor;
a fourth transistor of the second polarity type and having a control terminal and first and second terminals, the first terminal of the fourth transistor coupled to the second terminal of the second transistor;
a fifth transistor having a control terminal coupled to the control terminal of the third transistor; and
a sixth transistor having a control terminal coupled to the control terminal of the fourth transistor.

2. The amplifier of claim 1, wherein the fifth transistor is of the second polarity type, and the sixth transistor is of the first polarity type.

3. The amplifier of claim 1, wherein the fifth transistor is of the first polarity type, and the sixth transistor is of the second polarity type.

4. The amplifier of claim 1, wherein the first transistor is smaller than the third transistor, and the third transistor is smaller than the second transistor.

5. The amplifier of claim 1, wherein the first, second, third, fourth, fifth, and sixth transistors are bipolar junction transistors, the first polarity type is NPN, and the second polarity type is PNP.

6. The amplifier of claim 1, further comprising:
a transconductance circuit having an input and an output; and
a voltage gain circuit having an input and an output, the input of the voltage gain circuit coupled to the output of the transconductance circuit, and the output of the voltage gain circuit coupled to the control terminals of first and second transistors.

7. The amplifier of claim 6, wherein:
the fifth transistor has first and second terminals;
the sixth transistor has first and second terminals;
the first terminal of the first transistor is coupled to a first supply voltage terminal;
the second terminal of the second transistor is coupled to a second supply voltage terminal;
the first terminal of the third transistor is coupled to the voltage gain circuit and to the first terminal of the fifth transistor;
the second terminal of the third transistor is coupled to the second terminal of the fifth transistor; and
the second terminal of the fourth transistor is coupled to the voltage gain circuit and to the second terminal of the sixth transistor; and
the first terminal of the fourth transistor is coupled to the first terminal of the sixth transistor.

8. The amplifier of claim 1, further comprising:
a first current source circuit coupled between a first supply voltage terminal and the control terminal of the first transistor;
a second current source circuit coupled between a second supply voltage terminal and the control terminal of the second transistor;
a third current source circuit coupled between the first supply voltage terminal and the first terminal of the third transistor; and
a fourth current source circuit coupled between the second supply voltage terminal and the second terminal of the fourth transistor.

9. The amplifier of claim 8, wherein the third transistor is a diode-connected transistor, and the fourth transistor is a diode-connected transistor.

10. An amplifier, comprising:
an input stage circuit having first and second terminals;
a voltage gain circuit having a first terminal coupled to the first terminal of the input stage circuit and having a second terminal coupled to the second terminal of the input stage circuit, the voltage gain circuit having a third terminal;
a first transistor of a first polarity type and having a control terminal coupled to the third terminal and having first and second terminals;
a second transistor of a second polarity type and having a control terminal coupled to the third terminal and having a control terminal and first and second terminals;
a third transistor of the first polarity type and having a control terminal and first and second terminals, the second terminal of the third transistor coupled to the first terminal of the second transistor;
a fourth transistor of the second polarity type and having a control terminal and first and second terminals, the first terminal of the fourth transistor coupled to the second terminal of the second transistor;
a fifth transistor having a control terminal coupled to the control terminal of the third transistor; and
a sixth transistor having a control terminal coupled to the control terminal of the fourth transistor.

11. The amplifier of claim 10, wherein the input stage circuit includes a transconductance circuit.

12. The amplifier of claim 10, wherein:
the fifth transistor has first and second terminals;
the sixth transistor has first and second terminals;
the first terminal of the first transistor is coupled to a first supply voltage terminal;
the second terminal of the second transistor is coupled to a second supply voltage terminal;
the first terminal of the third transistor is coupled to the voltage gain circuit and to the first terminal of the fifth transistor;
the second terminal of the third transistor is coupled to the second terminal of the fifth transistor; and
the second terminal of the fourth transistor is coupled to the voltage gain circuit and to the second terminal of the sixth transistor; and
the first terminal of the fourth transistor is coupled to the first terminal of the sixth transistor.

13. The amplifier of claim 10, further including:
a first current source circuit coupled between a first supply voltage terminal and the control terminal of the first transistor;
a second current source circuit coupled between a second supply voltage terminal and the control terminal of the second transistor;
a third current source circuit coupled between the first supply voltage terminal and the first terminal of the third transistor; and
a fourth current source circuit coupled between the second supply voltage terminal and the second terminal of the fourth transistor.

14. The amplifier of claim 13, wherein the first and second current source circuits are configured to produce approximately a same amount of current, and the first and second current source circuits are configured to produce approximately a same amount of current.

15. The amplifier of claim 10, wherein the first, second, third, and fourth transistors are field effect transistors.

16. An amplifier, comprising:
base-connected bipolar junction transistors (BJTs) of different polarity types, the base-connected BJTs having a first terminal and a second terminal;
a first transistor of a first polarity type and having a control terminal coupled to the first terminal of the base-connected BJTs, and having first and second terminals;
a second transistor of a second polarity type and having a control terminal coupled to the second terminal of the base-connected BJTs, and having a control terminal and first and second terminals;
a third transistor of the first polarity type and having a control terminal and first and second terminals, the second terminal of the third transistor coupled to the first terminal of the second transistor;
a fourth transistor of the second polarity type and having a control terminal and first and second terminals, the first terminal of the fourth transistor coupled to the second terminal of the second transistor;
a fifth transistor having a control terminal coupled to the control terminal of the third transistor; and
a sixth transistor having a control terminal coupled to the control terminal of the fourth transistor.

17. The amplifier of claim 16, further comprising:
a transconductance circuit having an input and an output;
a first current mirror coupled to the transconductance circuit and to the base-connected BJTs; and
a second current mirror coupled to the transconductance circuit and to the base-connected BJTs.

18. The amplifier of claim 17, wherein:
the fifth transistor has first and second terminals;
the sixth transistor has first and second terminals;
the first terminal of the first transistor is coupled to a first supply voltage terminal;
the second terminal of the second transistor is coupled to a second supply voltage terminal;
the first terminal of the third transistor is coupled to the first current mirror and to the first terminal of the fifth transistor;
the second terminal of the third transistor is coupled to the second terminal of the fifth transistor; and
the second terminal of the fourth transistor is coupled to the second current mirror and to the second terminal of the sixth transistor; and
the first terminal of the fourth transistor is coupled to the first terminal of the sixth transistor.

19. The amplifier of claim 18, wherein the third, fourth, fifth, and sixth transistors are bipolar junction transistors, the first polarity type is NPN, the second polarity type is PNP, the fifth transistor is of the second polarity, and the sixth transistor is of the first polarity type.

20. The amplifier of claim 19, wherein bases of the third and fifth transistors are coupled together, and bases of the fourth and sixth transistors are coupled together.
